(19) United States
(12) Patent Application Publication
(10) Pub. No.: US 2025/0078923 A1
(43) Pub. Date: Mar. 6, 2025

(54) A CONFIGURATION MEMORY CELL

(71) Applicant: Microsemi SoC Corp., Chandler, AZ (US)

(72) Inventor: Victor Nguyen, San Ramon, CA (US)

(21) Appl. No.: 18/821,885

(22) Filed: Aug. 30, 2024

Related U.S. Application Data
(60) Provisional application No. 63/580,339, filed on Sep. 1, 2023.

(51) Int. Cl. G11C 13/00

(52) U.S. Cl. CPC G11C 13/003; G11C 13/0028; G11C 13/0069

(57) ABSTRACT

An apparatus may include a first inverter, a second inverter, a first access transistor, and a second access transistor. The first inverter and a second inverter may be cross-coupled between a first node and a second node to store a signal state represented by voltage values at the first node and the second node. The first and second inverters may be configured to operate reliably under voltage conditions higher than a positive supply voltage of the apparatus. The first access transistor may selectively couple the first node to a bit line, and allow direct control of the first node during access operations. The second access transistor may selectively couple the second node to the bit line, and allow direct control of the second node during access operations. The respective positive supply inputs of the first inverter and the second inverter may be to couple to a voltage supply associated with a higher voltage level than the positive supply voltage of the apparatus.

### CROSS-REFERENCE TO RELATED APPLICATION

This application claims the benefit under 35 U.S.C. § 119(e) of U.S. Provisional Patent Application Ser. No. 63/580,339, filed Sep. 1, 2023, the disclosure of which is hereby incorporated herein in its entirety by this reference.

### BACKGROUND

Storage elements (e.g., volatile storage elements, without limitation) are utilized in a variety of operational contexts.

### BRIEF DESCRIPTION OF THE DRAWINGS

To easily identify the discussion of any particular element or act, the most significant digit or digits in a reference number refer to the figure number in which that element is first introduced.

FIG. 1 is a schematic diagram depicting the layout of a memory cell designed to be SEU immune while operating in a high-voltage (HV) domain, in accordance with one or more examples.

FIG. 2 is a schematic diagram of a memory cell that offers SEU immunity while operating in a high-voltage (HV) domain, in accordance with one or more examples.

FIG. 3 is a schematic diagram of a memory cell that offers SEU immunity while operating in a high-voltage (HV) domain, in accordance with one or more examples.

FIG. 4 is a block diagram depicting a memory system that includes a memory cell and its associated driver circuitry.

FIG. 5 is a voltage bias and state table depicting operation states of a configuration memory cell or system, such as memory cell of FIG. 1, memory cell of FIG. 2, memory cell of FIG. 3, or memory system of FIG. 4, in accordance with one or more examples.

FIG. 6 illustrates an example process for a two-phase write logic low value (a ‘0’) operation to an example memory cell discussed herein, in accordance with one or more examples.

FIG. 7 illustrates an example process for a two-phase write logic high value (a ‘1’) operation to an example memory cell discussed herein, in accordance with one or more examples.

FIG. 8 is a block diagram of circuitry that, in some examples, may be used to implement various functions, operations, acts, processes, or methods disclosed herein.

### DETAILED DESCRIPTION

In the following detailed description, reference is made to the accompanying drawings, which form a part hereof, and in which are shown, by way of illustration, specific examples of embodiments in which the present disclosure may be practiced. These embodiments are described in sufficient detail to enable a person of ordinary skill in the art to practice the present disclosure. However, other embodiments may be utilized, and structural, material, and process changes may be made without departing from the scope of the disclosure.

The illustrations presented herein are not meant to be actual views of any particular method, system, device, or structure, but are merely idealized representations that are employed to describe the embodiments of the present disclosure. The drawings presented herein are not necessarily drawn to scale. Similar structures or components in the various drawings may retain the same or similar numbering for the convenience of the reader; however, the similarity in numbering does not mean that the structures or components are necessarily identical in size, composition, configuration, or any other property.

The following description may include examples to help enable one of ordinary skill in the art to practice the disclosed embodiments. The use of the terms “exemplary,” “by example,” and “for example,” means that the related description is explanatory, and though the scope of the disclosure is intended to encompass the examples and legal equivalents, the use of such terms is not intended to limit the scope of an embodiment or this disclosure to the specified components, steps, features, functions, or the like.

It will be readily understood that the components of the embodiments as generally described herein and illustrated in the drawing could be arranged and designed in a wide variety of different configurations. Thus, the following description of various embodiments is not intended to limit the scope of the present disclosure, but is merely representative of various embodiments. While the various aspects of the embodiments may be presented in drawings, the drawings are not necessarily drawn to scale unless specifically indicated.

Furthermore, specific implementations shown and described are only examples and should not be construed as the only way to implement the present disclosure unless specified otherwise herein. Elements, circuits, and functions may be shown in block diagram form in order not to obscure the present disclosure in unnecessary detail. Conversely, specific implementations shown and described are exemplary only and should not be construed as the only way to implement the present disclosure unless specified otherwise herein. Additionally, block definitions and partitioning of logic between various blocks is exemplary of a specific implementation. It will be readily apparent to one of ordinary skill in the art that the present disclosure may be practiced by numerous other partitioning solutions. For the most part, details concerning timing considerations and the like have been omitted where such details are not necessary to obtain a complete understanding of the present disclosure and are within the abilities of persons of ordinary skill in the relevant art.

Those of ordinary skill in the art would understand that information and signals may be represented using any of a variety of different technologies and techniques. Some drawings may illustrate signals as a single signal for clarity of presentation and description. It will be understood by a person of ordinary skill in the art that the signal may represent a bus of signals, wherein the bus may have a variety of bit widths and the present disclosure may be implemented on any number of data signals including a single data signal.

The various illustrative logical blocks, modules, and circuits described in connection with the embodiments disclosed herein may be implemented or performed with a general purpose processor, a special purpose processor, a Digital Signal Processor (DSP), an Integrated Circuit (IC), an Application Specific Integrated Circuit (ASIC), a Field Programmable Gate Array (FPGA) or other programmable logic device, discrete gate or transistor logic, discrete hardware components, or any combination thereof designed to perform the functions described herein. A general-purpose processor (may also be referred to herein as a host processor or simply a host) may be a microprocessor, but in the alternative, the processor may be any conventional processor, controller, microcontroller, or state machine. A processor may also be implemented as a combination of computing devices, such as a combination of a DSP and a microprocessor, a plurality of microprocessors, one or more microprocessors in conjunction with a DSP core, or any other such configuration. A general-purpose computer including a processor is considered a special-purpose computer while the general-purpose computer executes computing instructions (e.g., software code) related to embodiments of the present disclosure.

The embodiments may be described in terms of a process that is depicted as a flowchart, a flow diagram, a structure diagram, or a block diagram. Although a flowchart may describe operational acts as a sequential process, many of these acts can be performed in another sequence, in parallel, or substantially concurrently. In addition, the order of the acts may be re-arranged. A process may correspond to a method, a thread, a function, a procedure, a subroutine, a subprogram, without limitation. Furthermore, the methods disclosed herein may be implemented in hardware, software, or both. If implemented in software, the functions may be stored or transmitted as one or more instructions or code on computer-readable media. Computer-readable media includes both computer storage media and communication media including any medium that facilitates transfer of a computer program from one place to another.

Any reference to an element herein using a designation such as “first,” “second,” and so forth does not limit the quantity or order of those elements, unless such limitation is explicitly stated. Rather, these designations may be used herein as a convenient method of distinguishing between two or more elements or instances of an element. Thus, a reference to first and second elements does not mean that only two elements may be employed there or that the first element must precede the second element in some manner. In addition, unless stated otherwise, a set of elements may comprise one or more elements.

As used herein, the term “substantially” in reference to a given parameter, property, or condition means and includes to a degree that one of ordinary skill in the art would understand that the given parameter, property, or condition is met with a small degree of variance, such as, for example, within acceptable manufacturing tolerances. By way of example, depending on the particular parameter, property, or condition that is substantially met, the parameter, property, or condition may be at least 90% met, at least 95% met, or even at least 99% met.

As used herein, any relational term, such as “over,” “under,” “on,” “underlying,” “upper,” “lower,” without limitation, is used for clarity and convenience in understanding the disclosure and accompanying drawings and does not connote or depend on any specific preference, orientation, or order, except where the context clearly indicates otherwise.

In this description the term “coupled” and derivatives thereof may be used to indicate that two elements co-operate or interact with each other. When an element is described as being “coupled” to another element, then the elements may be in direct physical or electrical contact or there may be intervening elements or layers present. In contrast, when an element is described as being “directly coupled” to another element, then there are no intervening elements or layers present. The term “connected” may be used in this description interchangeably with the term “coupled,” and has the same meaning unless expressly indicated otherwise or the context would indicate otherwise to a person having ordinary skill in the art.

A “volatile storage cell” is a type of data storage that requires continuous power to maintain the information stored within it. A volatile storage cell represents information via its state (e.g., charged, or uncharged, high voltage or low voltage, without limitation) and it requires continuous power to keep its state. If the power supply to the cell is interrupted or turned off, the volatile storage cell loses state and the information stored in the volatile storage cell is lost.

Examples of volatile storage cells include, but are not limited to: latch circuits, flip-flop circuits, and circuits including cross-coupled inverters. Some field-programmable gate arrays (FPGAs) include configuration memory cells that include volatile storage cells. Further, static random-access memory (SRAM) cells include volatile storage cells.

The terms “memory cell” and “volatile storage cell” are used interchangeable herein to mean a “volatile storage cell.” When utilized in an FPGA, an example memory cell discussed herein may be referred to as a “configuration memory cell” or just a “configuration cell.”

Traditional configuration memory cells utilized in FPGAs are unable to be written to or read from when powered up in a high-voltage domain (voltage conditions higher than a positive supply voltage) due to stress limitations and specific internal connections of transistors. In some cases, a traditional configuration memory cell powered by a high voltage power source is powered down, powered up with a lower voltage power source, the various access operations are performed, the configuration memory cell is power down again, and then powered up again with the higher voltage power source. The powering down and powering up consumes power and reduces performance. Here, “positive supply voltage” refers to the standard positive supply voltage (e.g., VDD, without limitation) used to represent standard logic high level (logic ‘1’) for low voltage components. Non-limiting examples of voltage levels of VDD include 1.2V logic, 1.8V logic, 2.5V logic, 3.3V logic, and 5V logic.

By way of non-limiting example, an FPGA may use VDD of 1.2V for standard logic level of low-voltage components, and a positive high voltage (VPHV) of 9V for programming or configuration operations.

One or more examples relate, generally, to a configuration cell, and Field Programmable Gate Arrays (FPGAs) including the same. The configuration cell is designed to withstand Single Event Upsets (SEUs) in high-voltage (HV) environments. Such a configuration cell may be utilized in Field Programmable Gate Arrays (FPGAs), where SEUs can pose significant reliability concerns.

In one or more examples, modifying the access points to the configuration cell and including an additional WordLine (WL), as compared to traditional configuration cells utilized in FPGAs, enables the configuration cell to be written and read while under high voltage without exposing any single device to excessive stress that could cause SEU.

In one or more examples, such a memory cell of a memory device or system, or an FPGA, may be directly accessible, in constant time, without having to access other memory cells of the memory.

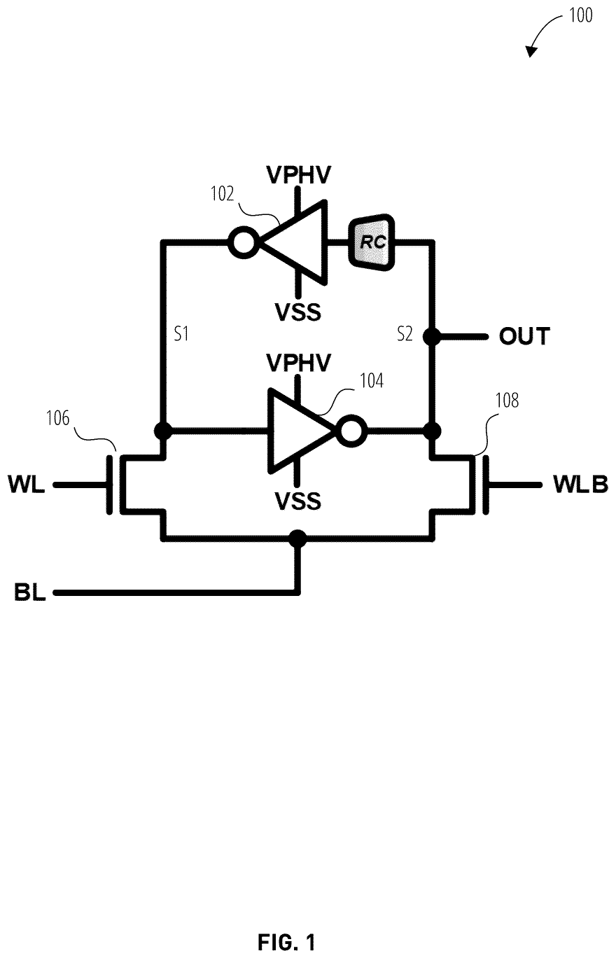

FIG. 1 is a schematic diagram depicting the layout of a memory cell 100 designed to be SEU immune while operating in a high-voltage (HV) domain, in accordance with one or more examples.

Memory cell 100 includes PMOS and NMOS transistors arranged in a configuration that defines the cell's state.

Specifically, memory cell 100 includes a pair of cross-coupled inverters, first inverter 102 and second inverter 104, with the respective output of each inverter coupled (e.g., electrically coupled, without limitation) to respective inputs of the other inverter. Notably, in a case where the signal state of memory cell 100 is configuration data (e.g., data the value of which determines the behavior of an FPGA's logic elements, without limitation), a signal on output OUT may carry the stored configuration data from the memory cell 100. The memory cell 100 has two stable states, here, logic low ‘0’ and logic high ‘1’. The cross-coupled inverters are the state retaining element of memory cell 100. The cross-coupled inverters form a configuration that allows memory cell 100 to define and maintain a stable state during operation. This configuration enables the memory cell to hold either a logic ‘0’ or logic ‘1’ depending on input signals.

The state of memory cell 100 is stored at the storage nodes S1 and S2, which use voltages values corresponding to VPHV and VSS to store signal state of memory cell 100. The cross-coupling configuration of first inverter 102 and second inverter 104 reinforce the voltage levels at nodes S1 and S2 to ensure that the cell maintains a stable state.

Respective positive voltage supply inputs of both inverters are coupled to a first voltage supply VPHV and respective ground inputs of both inverters are coupled to a second voltage supply VSS. VPHV is utilized to represent a logic high signal state (a logic ‘1’), and VSS is utilized to represent the logic low signal state (a logic ‘0’0) within memory cell 100.

The respective inputs for receiving the first supply voltage VPHV are operable to be coupled solely to the first voltage supply. In one or more examples, the respective inputs for receiving first supply voltage VPHV are directly coupled to the voltage supply, with no intervening elements that could switch the supply to a lower voltage level.

The outputs of the inverters are connected to respective ones of first access device 106 and second access device 108, which are controlled by WordLines WL and WLB, respectively. These access devices selectively transfer the signal state (or its complement) between storage nodes S1 and S2 of memory cell 100 and the bit line (BL). During a write operation, the access devices allow transfer of signal state and complementary signal state from the bit line to the appropriate storage node of memory cell 100. During a read operation, the access devices allow transfer signal state and complementary signal state from the appropriate storage nodes of memory cell 100 to the bit line.

The terms “single event upset” and “SEU” refer to a change in state of the source node or drain node of a transistor resulting from one or more ionizing particles affecting the transistor. For example, a source node or drain node of a transistor may be struck by a heavy ion which may cause an influx of electron-hole pairs which may drive the source node or drain node higher or lower in voltage. The higher or lower voltage at the source node or drain node of the transistor may result in a change in a state (e.g., “on” to “off” or “off” to “on”) of the transistor. The term “SEU” may be applied to a transistor to indicate that the transistor has changed state based on an SEU. The term “SEU” may also be applied to a device (e.g., a volatile storage element, without limitation) to indicate that the device has changed state based on an SEU, for example, a bit of data stored by the volatile storage element may change as a result of the SEU.

The terms “single event upset resistant” and “SEU-resistant,” may refer to a state of being more resistant to SEU than another system, circuit, or device. In particular, an SEU-resistant system, circuit, or device may include one or more elements that may allow the SEU-resistant system, circuit, or device to be less likely to experience an SEU than systems, circuits, or devices that do not include the one or more elements.

SEU resistance may improve a system, circuit, or device by enhancing its ability to maintain stable latch states, even when subjected to disturbances. For example, SEU resistance may improve how a system, circuit, or device responds to an event that inadvertently enables a word line for a short period of time. Examples of events that may enable a word line for a short period of time include user error or a bug in a control system that drives a word line without limitation.

Volatile storage cells are particularly susceptible to SEUs. As a non-limiting example, an SEU can cause a transistor node in an inverter within a pair of cross-coupled inverters in a volatile storage element to change states, potentially altering the stored data bit.

Memory cells 100 includes an impedance element (RC) in a circuit, specifically in paths that include components vulnerable to SEUs. For instance, adding an impedance element in the loop between cross-coupled inverters increases the circuit's time constant (e.g., RC time). This increased time constant makes the circuit less susceptible to SEUs, which are typically short-duration events. An SEU might cause a rapid voltage change that could change (e.g., flip) the state of cross-coupled inverters. The impedance element RC resists rapid voltage changes across the transistors, helping the inverters maintain or revert to their pre-SEU state before the incorrect state is fully established. An impedance element, characterized by its suitable resistance to charge flow that could alter the state of the volatile storage device, can include components like resistive random-access memory (ReRAM), an anti-fuse, or a vertical resistor, without limitation.

FIG. 1 is a depicts the memory cell layout, but does not explicitly depict the additional WordLine or modification to access devices mentioned above.

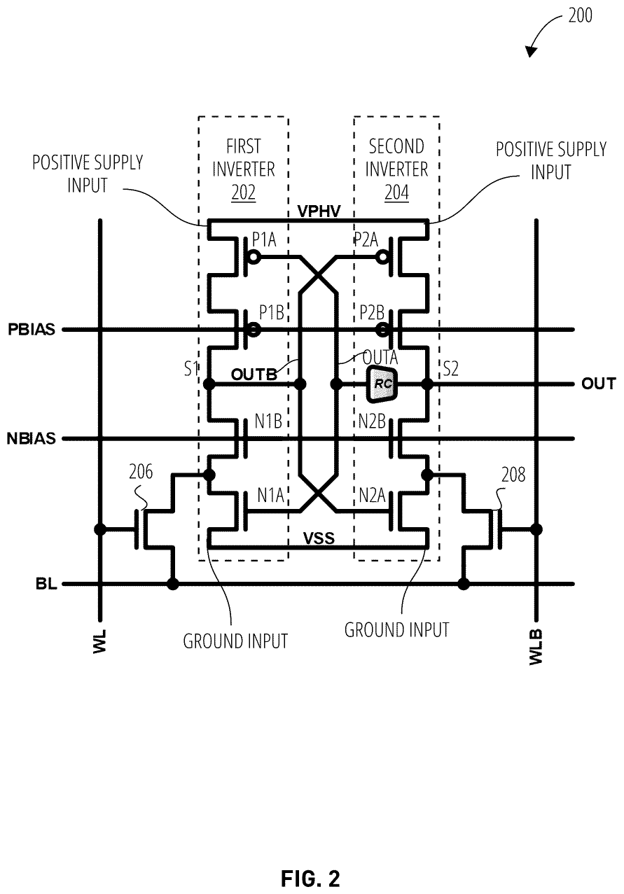

FIG. 2 is a schematic diagram of a memory cell 200 that offers SEU immunity while operating in a high-voltage (HV) domain, in accordance with one or more examples. Memory cell 200 is a non-limiting example of a memory cell 100.

As discussed, below, memory cell 200 supports a two-phase write operation and a two-phase read operation, that respectively allow memory cell 100 to change states in a manner that ensure that no single device within the cell is exposed to excessive voltage stress, limiting susceptibility to SEUs.

Memory cell 200 includes a first inverter 202, a second inverter 204, a first access transistor 206 and a second access transistor 208. First inverter 202 and second inverter 204 are cross-coupled to form the state retaining element of memory cell 100 as discussed above.

First inverter 202 includes two PMOS transistors P1A and P1B connected in series and two NMOS transistors N1A and N1B connected in series. Similarly, second inverter 204 includes two PMOS transistors P2A and P2B connected in series, and two NMOS transistors N2A and N2B connected in series. NMOS transistors N1A, N1B of first inverter 202 and N2A, N2B of second inverter 204 respectively act as a pull-up network, and PMOS transistors P1A, P1B of first inverter 202 and P2A, P2B of second inverter 204 respectively act as a pull-down network.

In first inverter 202 and second inverter 204, the sources of N1A and N2A are connected to a voltage supply line, VSS, which is associated with a logic low level (0V), and the drains of N1A and N2A are connected to the sources of NMOS transistors N1B and N2B. Drains of N1B and N2B are connected to nodes S1 and S2, respectively.

In first inverter 202 and second inverter 204, the sources of P1A and P2A are connected to the first voltage supply line VPHV, associated with a logic high level. The drains of P1A and P2A are connected to the sources of PMOS transistors P1B and P2B, respectively. Drains of P1B and P2B are connected to nodes S1 and S2, respectively.

Single instances of PMOS transistors P1A, P1B, P2A, and P2B are depicted, and single instances of NMOS transistors N1A, N1B, N2A and N2B are depicted in FIG. 2. The number of NMOS and PMOS transistors used in the cross-coupled inverters 202 and 204 may be chosen to balance performance, area, and power consumption. In the case of one or more of MOS transistors P1A, P1B, P2A, and P2B or NMOS transistors N1A, N1B, N2A and N2B, multiple transistors may be present in a stacked configuration. In a stacked configuration, the transistors are arranged such that the drain of one transistor is connected to the source of another. This stacking allows for a division of voltage across the transistors, helping to manage the voltage stress within the devices (e.g., ensuring voltage across terminal nodes of the transistors are within tolerances, without limitation), including during access operations discussed herein (e.g., read and two-phase write operations, discussed herein, without limitation).

### Nonuniform Voltage Tolerance

First access transistor 206, first access transistor 206, PMOS transistors P1A, P1B, P2A, and P2B, and NMOS transistors N1A, N1B, N2A, and N2B exhibit nonuniform voltage tolerance. A nonuniform voltage tolerant transistor can tolerate different voltage levels across its different terminals (e.g., gate-drain (Vgd), gate-source (Vgs), drain-source (Vds)). In one or more examples, such a transistor may handle higher voltages across Vgs and Vgd and have lower voltage tolerance across Vds. If the Vds voltage exceeds the tolerance threshold (what a transistor can tolerate for more than a negligible amount of time), the transistor may suffer damage over time, leading to potential breakdown, short circuits, or leakage current.

Here, first access transistor 206, first access transistor 206, PMOS transistors P1A, P1B, P2A, and P2B, and NMOS transistors N1A, N1B, N2A, and N2B are not high-voltage tolerant across their drain-source nodes. These transistors can tolerate voltages across their drain-source nodes up to VDD, but not above (e.g., could not tolerate VPHV). These transistors can tolerate voltages at least up to VPHV, and optionally beyond, across their gate-drain nodes and their gate-source nodes.

### NBIAS

The respective gates of N1B and N2B are connected to the NBIAS line (NMOS transistors N1A and N2A are not connected to the NBIAS line in the specific example depicted by FIG. 2), which supplies bias voltage V_{NBIAS} (voltage not depicted). These transistors are biased NMOS transistors. NBIAS sets the gate-source voltage (Vgs) of the NMOS transistors (here, N1B and N2B). By setting NBIAS to an appropriate level, the gate-source voltage (Vgs) of the NMOS transistors is managed such that the transistors operate within their safe region. While the NBIAS line directly controls Vgs, it indirectly controls Vds by maintaining the proper operating conditions for the NMOS transistors to stay in a region. NBIAS helps ensure that the source voltages V_{S} of the NMOS transistors stay low enough relative to the drain voltages V_{D}, preventing Vds from exceeding the transistor's tolerance. When the gates of N1B and N2B are driven by NBIAS, their source voltages are constrained to be a fraction of the drain voltage V_{D}, limiting the voltage stress across them.

### PBIAS

The respective gates of P1B and P2B are connected to the PBIAS line (PMOS transistors P1A and P2A are not connected to PBIAS line in the specific example depicted by FIG. 2), which supplies a bias voltage V_{PBIAS} (voltage not depicted). These transistors P1A, P1B, P2A and P2B are biased PMOS transistors. PBIAS sets the gate-source voltage of the PMOS transistors (here, P1B and P2B). By setting PBIAS at an appropriate level, the gate-source voltage (Vgs) of the PMOS transistors is managed such that the transistors operate within their safe region. While PBIAS directly controls Vgs, it indirectly controls Vds by ensuring that respective PMOS transistors stay in a region where the drain-source voltage does not exceed the tolerance. PBIAS can ensure that the drain of P1B or P2B does not rise too high relative to the source, keeping Vds within tolerance limits. So, the PBIAS line effectively conditions P1B and P2B so that their respective drain voltages V_{D} are constrained to be a fraction of their respective source voltages VS, limiting the voltage stress across them.

In one or more examples, the bias levels of bias voltages PBIAS and NBIAS applied to gates of PMOS and NMOS transistors, and the set of respective PMOS and NMOS transistors to which PBIAS or NBIAS voltages are applied, is chosen to ensure that the drain-source voltages remain within limits (e.g., limits at least partially defined by specific voltage tolerances across specific nodes of the transistor, which may be non-uniform, without limitation), including for operation of the memory cell 200 in a high voltage domain VPHV. In one or more examples, the amount of bias may be chosen to provide sufficient gate control while reducing the impact of voltage stress on the transistors. This ensures that the transistors operate reliably without exceeding respective voltage tolerances.

In one or more examples, The voltage tolerances of the transistors, particularly their drain-source (Vds) limits, may be considered in the design of a memory cell 200. PMOS and NMOS transistors in the memory cell 200 are partially voltage tolerant, and so can withstand higher Vgs and Vgd voltages, but their Vds must be kept below a certain threshold (e.g., 1.2V) that is lower than the threshold that may be tolerated for Vgs and Vg.

As noted above, various designs contemplated herein ensure respective tolerances are met (e.g., not exceeded, without limitation), at least in part, by distributing the voltage across multiple transistors (e.g., in stacked configurations, without limitation) and by careful biasing.

In one or more examples, one or more parameters—transistor count, bias voltages, and voltage tolerances—may be pre-determined during a design phase to ensures that the memory cell 200 meets various specifications for read and write operations, including two-phase read and write operations, and resistance to SEUs. Process variation and operational conditions also may be considered during optimization to ensure the design performs consistently across different manufacturing batches and in various operating environments.

### WL and WLB

First access transistor 206 and second access transistor 208 serve as the interface between the bit line (BL) and the memory cell 200. The arrangement of first access transistor 206 and second access transistor 208, controlled by WordLines (WL and WLB), allows memory cell 200 to be written to and read from while maintaining high-voltage operation, as discussed below. The presence of both WordLine WL and WLB is an enhancement compared to traditional memory cell designs that might use a single WordLine. This dual-WordLine offers better control over read and write operations, particularly in high-voltage domains, as it allows the selective activation of first access transistor 206 and second access transistor 208 to reduce the stress on any single device.

The drain of first access transistor 206 is connected to the node between N1A and N1B in first inverter 202 (i.e., OUTB), and the drain of second access transistor 208 is connected to the node between N2A and N2B in second inverter 204 (i.e., OUTA). The sources of both access transistors are connected to the Bit Line (BL).

The gates of first access transistor 206 and second access transistor 208 are controlled by the Word Lines (WL) and WLB, respectively. Signals on WL and WLB determine when the access transistors are enabled, allowing data to be written to or read from memory cell 100 via BL.

### Optional RC Element

An optional RC Element is connected between node S2 and the output OUTA of first inverter 202. This element increases the circuit's RC time constant, providing resistance against SEUs by helping the inverters maintain or recover to their stable states after a transient event before an incorrect state can be fully established. The output OUTB of second inverter 204 is coupled to node S1.

A BL driver (driver circuit not depicted) may be realized with solely low voltage (LV) tolerant transistors to save area and power. Write lines WL and WLB drivers (driver circuit(s) not depicted) may be realized with solely low voltage (LV) tolerant transistors, which reduces area and power. Solely low voltage tolerant transistors are not even partially high voltage tolerant.

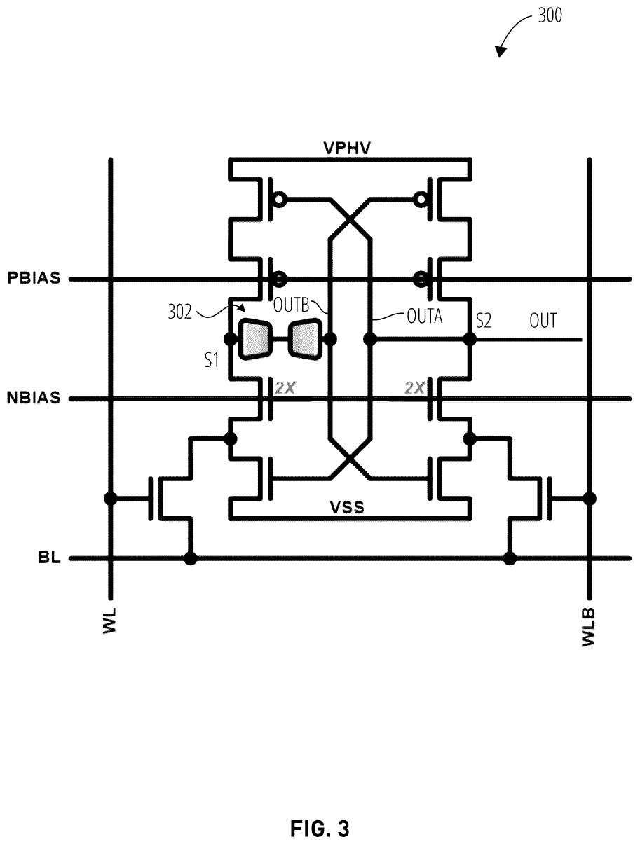

FIG. 3 is a schematic diagram of a memory cell 300 that offers SEU immunity while operating in a high-voltage (HV) domain, in accordance with one or more examples. Memory cell 300 is a non-limiting example of a memory cell 100.

The memory cell 300 is similar to memory cell 200 except the SEU-resistant element 302 is coupled between the output of second inverter and node S1. In this example, the SEU-resistant element (RC) comprises two resistive random access memory (ReRam) devices. The number and placement (e.g., between output OUTB and S1, between output OUTA and S2, or both, without limitation) of resistive ReRam devices may depend, as a non-limiting example, on specific operating conditions.

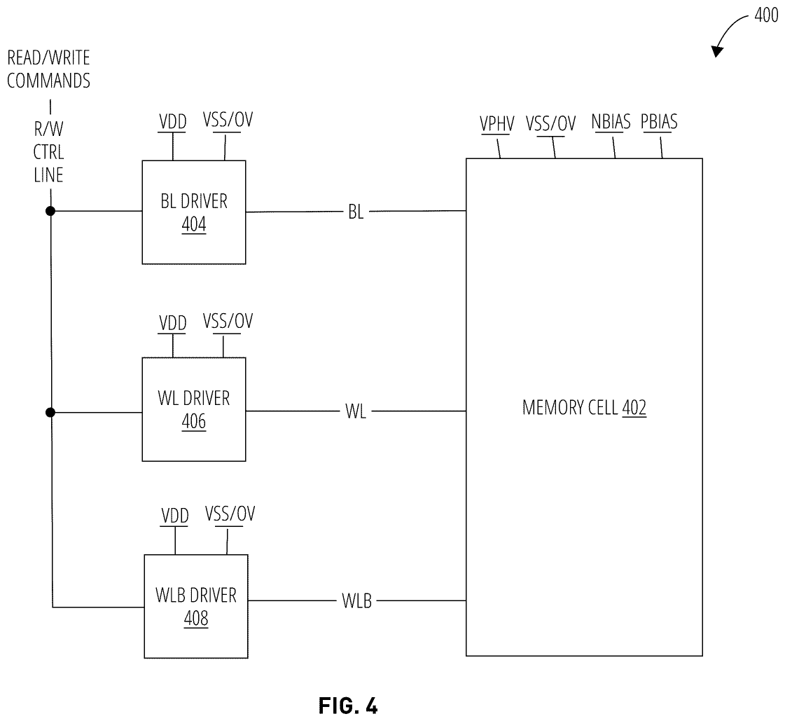

FIG. 4 is a block diagram depicting a memory system 400 that includes a memory cell 402 and its associated driver circuitry. This system is designed to manage high-voltage operations and low-voltage control signals for read and write operations.

Memory system 400 includes BL driver 404, WL driver 406, WLB driver 408 and memory cell 402.

Memory cell 402 is a memory cell that offers SEU immunity while operating in a high-voltage (HV) domain discussed herein, such as memory cell 100, memory cell 200 or memory cell 300, without limitation. Here, memory cell 402 is connected to both high-voltage (VPHV) and low-voltage (VSS/0V) supplies. Memory cell 402 is also connected to supplies for NBIAS and PBIAS voltages discussed above.

VPHV is the high-voltage supply connected to the memory cell 402, ensuring that it can operate in a high-voltage domain. VSS/0V is a low-voltage (ground) supply connected to both the memory cell 402 and the drivers (BL driver 404, WL driver 406 and WLB driver 408). The drivers may use VSS/0V as a reference voltage for their low-voltage operations.

BL driver 404 controls the bit line (BL), which interfaces with the memory cell 402 for read and write operations. The BL driver 404 is powered by VDD and VSS/0V, indicating that it operates in a low-voltage domain. The BL driver 404 receives read/write commands and generates appropriate signals to drive the bit line (BL), enabling data to be written to or read from the memory cell.

The WL driver 406 controls (e.g., activates/deactivates, without limitation) the word line (WL), which is used to allow access to the memory cell 402 during read and write operations. Like the BL driver 404, the WL driver 406 is powered by VDD and VSS/0V, indicating it operates in the low-voltage domain. The WL driver receives read/write commands and drives the word line (WL) to control access to the memory cell 402.

The WLB driver 408 controls (e.g., activates/deactivates, without limitation) the complementary word line (WLB), which is to selectively access the memory cell 402 during read and write operations. WLB driver 408 is powered by VDD and VSS/0V, indicating it operates in the low-voltage domain. The WLB driver 408 acts in coordination with the WL driver 406 to ensure proper access to the memory cell 402 during access operations (e.g., read and write, without limitation).

Here, the term “activate” when used in connection with a word line means to apply a voltage to the word line that turns on the access transistors connected to it. Here, the term “deactivate” when used in connection with a word line means to apply a voltage (typically 0V or another appropriate level) to the word line that turns off the access transistors connected to it.

The read/write control line carries the commands that manage the operation of the BL driver 404, WL driver 406, and WLB driver 408. This control line determines whether the system is performing a read or write operation and adjusts the driver outputs accordingly.

In one or more examples, Memory cell 402 may support a write operation that respectively include two write phases: Phase 1 and Phase 2.

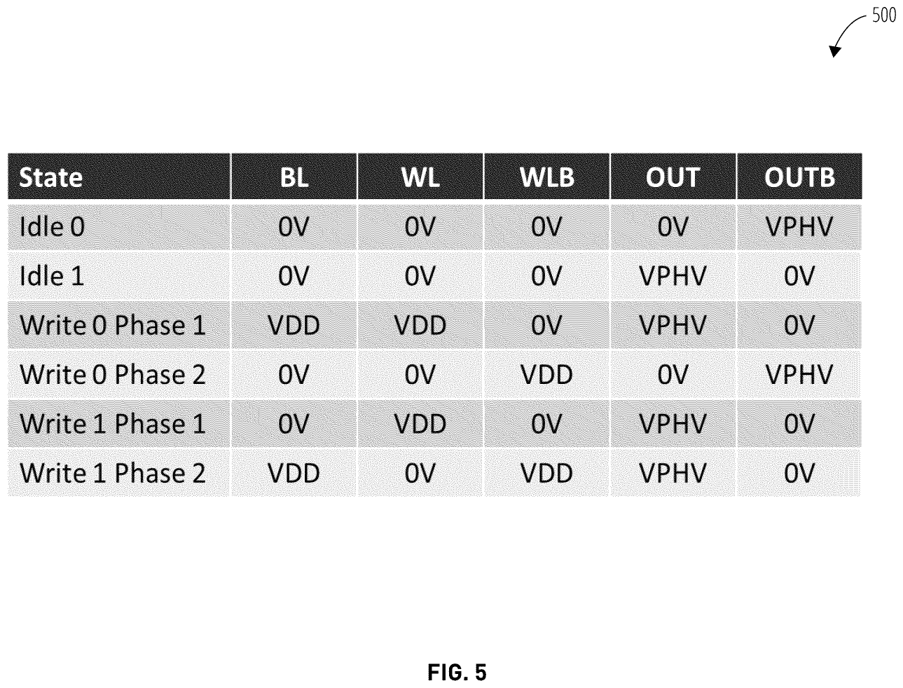

FIG. 5 is a voltage bias and state table depicting operation states of a configuration memory cell or system, such as memory cell 100, memory cell 200, memory cell 300 or memory system 400, in accordance with one or more examples.

The Voltage Bias & State Table depicted by FIG. 5 provides a detailed breakdown of the voltage levels on various signals in the memory cell (memory cell 100, memory cell 200, memory cell 300 or memory cell 402) during different operational states. The table demonstrates how the voltages on the Bit Line (BL), Word Line (WL), Complementary Word Line (WLB), and the outputs (OUT and OUTB) change during Idle and Write operations, specifically using a two-phase write process. This process ensures that the memory cell operates reliably under high-voltage conditions while minimizing the risk of erroneous state changes due to SEUs.

Regarding the columns of the table: BL (Bit Line) includes the voltage on BL, which is responsible for transferring data to and from the memory cell during read and write operations. WL (Word Line) includes voltages on WL, which controls the access transistor that connects the Bit Line to the storage node (S1). WLB (Complementary Word Line) includes voltages on WLB, which controls the complementary access transistor that connects the Bit Line to the complementary storage node (S2). OUT includes the voltage at storage node (S2). OUTB includes the voltage at the complementary storage node (S1).

The state column lists example states of the memory cell. For Idle state 0 and Idle state 1: BL, WL, and WLB are all at 0V; OUT and OUTB maintain stable logic levels, with OUT at 0V and OUTB at VPHV during Idle 0, and vice versa during Idle 1; and the memory cell holds its state, with no active read or write operation taking place.

In a two-phase access, the word line and the complementary word line are sequentially activated in access operations on the configuration memory cell. In one or more examples, in a two-phase operations for write 0 or write 1 discussed herein, the circuit preconditions the storage nodes, S1 and S2, by setting them to the opposite state (a preconditioned state) of the desired final value (the written state). This ensures that the correct logic levels can be established more robustly in the subsequent phase. The circuit then finalizes the state by switching the storage nodes from the preconditioned state to the state of the desired final value (the written state).

By having two access transistors controlled by WL and WLB, the BL can selectively and directly influence specific storage nodes S1 and S2 during respective phases of the access operation. This direct influence over the storage nodes allows for more precise setting of the desired logic levels.

This two-phase strategy, combined with the use of two distinct access devices that can separately provide access to storage nodes S1 and S2 of the memory cell, helps ensure that the memory cell's state is reliably written. The preconditioning in Phase 1 makes it easier to achieve the correct final state in Phase 2, reducing the risk of errors due to transient events like SEUs.

Write 0: Phase 1 and Write 0: Phase 2 relate to write of a logic ‘0’ to the memory cell, which is a two-phase operation. During Phase 1, BL sets the initial condition for the storage nodes, S1 and S2, to a logic ‘1’ at the memory cell, and the NMOS and PMOS transistors of the cross-coupled inverters stabilize the voltage levels at S1 and S2 at 0V and VPHV. In Phase 2, BL sets the fully written condition for the storage nodes, S1 and S2, to a logic ‘0’ at the memory cell, and the NMOS and PMOS transistors of the cross-coupled inverters stabilize the voltage levels at S1 and S2 at VPHV and 0, completing the write 0 operation.

In the first phase, Phase 0, BL is set to VDD so that, initially, a logic ‘1’ will be written to the memory cell. WL is set to VDD to enable the first access transistor. WLB is set to 0 to disable the complementary access transistor. With the first access transistor enabled and complementary access transistor disabled, BL can influence OUT (or S2) and OUTB (or S1). Specifically, the PMOS transistors in the cross-coupled inverters ensure that OUT (or S2) reaches VPHV and OUTB (or S1) reaches 0V in response to BL.

In the second phase, Phase 1, which occurs immediately after Phase 0, BL is set to 0 so that that a logic ‘0’ will be written to the memory cell. WL is set to 0V and WLB is set to VDD, which disables the first access transistor and enables the second, complementary access transistor. With the first access transistor disabled and the commentary access transistor enabled, BL can influence OUT (or S2) and OUTB (or S1). Specifically, the NMOS transistors in the cross-couped inverters ensure that OUT (or S2) reaches 0V and OUTB (or S1) reaches VPHV in response to BL.

Write 1: Phase 1 and Write 1: Phase 2 relate to writing a logic ‘1’ to the memory cell, which is a two-phase operation. During Phase 1, BL sets the initial condition for the storage nodes, S1 and S2, to a logic ‘0’ at the memory cell, and the NMOS and PMOS transistors of the cross-coupled inverters stabilize the voltage levels at S1 and S2 at VPHV and 0V. In Phase 2, BL sets the fully written condition for the storage nodes, S1 and S2, to a logic ‘1’ at the memory cell, and the NMOS and PMOS transistors of the cross-coupled inverters stabilize the voltage levels at S1 and S2 at 0V and VPHV, completing the Write 1 operation.

In the first phase, Phase 1, BL is set to 0V so that, initially, a logic ‘0’ will be written to the memory cell. WL is set to VDD to enable the first access transistor. WLB is set to 0V to disable the complementary access transistor. With the first access transistor enabled and the complementary access transistor disabled, BL can influence OUT (or S2) and OUTB (or S1). Specifically, the NMOS transistors in the cross-coupled inverters ensure that OUT (or S2) reaches 0V and OUTB (or S1) reaches VPHV in response to BL.

In the second phase, Phase 2, which occurs immediately after Phase 1, BL is set to VDD so that a logic ‘1’ will be written to the memory cell. WL is set to 0V, and WLB is set to VDD, which disables the first access transistor and enables the second, complementary access transistor. With the first access transistor disabled and the complementary access transistor enabled, BL can influence OUT (or S2) and OUTB (or S1). Specifically, the PMOS transistors in the cross-coupled inverters ensure that OUT (or S2) reaches VPHV and OUTB (or S1) reaches 0V in response to BL.

Notably, a write (whether 0 or a 1) has two phases, and each phase takes a single clock cycle. Thus, a write to a memory cell discussed herein takes two clock cycles.

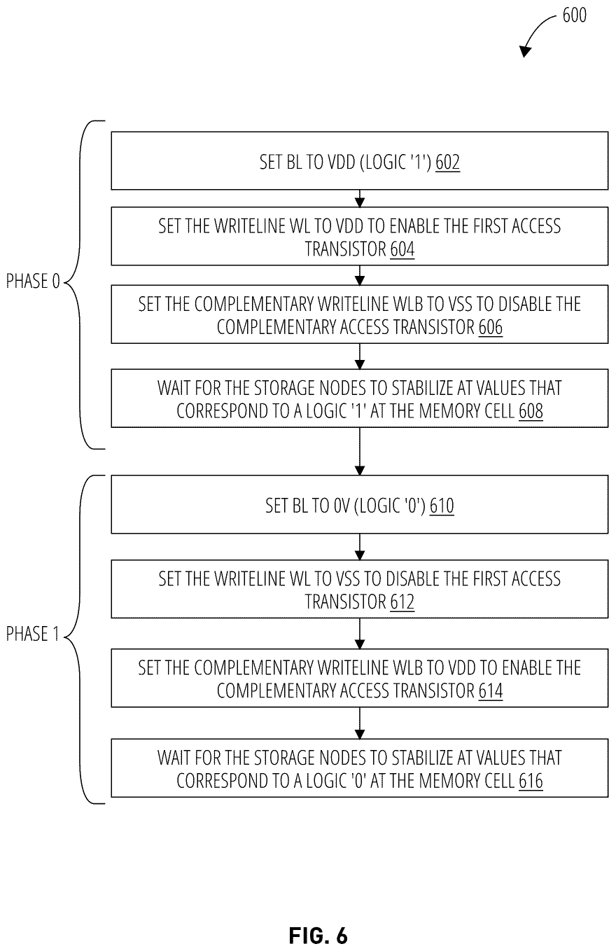

FIG. 6 illustrates an example process 600 for a two-phase wrote 0 operation to an example memory cell discussed herein (e.g., memory cell 100, memory cell 200, memory cell 300, memory cell 402), in accordance with one or more examples.

Although the example process 600 depicts a particular sequence of operations, the sequence may be altered without departing from the scope of the present disclosure. For example, some of the operations depicted may be performed in parallel or in a different sequence that does not materially affect the function of the process 600. In other examples, different components of an example device or system that implements the process 600 may perform functions at substantially the same time or in a specific sequence.

In one or more examples, some or a totality of operations of process 600 may be performed by a memory system 400.

In one or more examples, some or a totality of operations of process 600 may be performed by a logic circuit cooperatively with one or more drivers of BL, WL and WLB, discussed herein. As non-limiting examples, such as logic circuit may be integrated with a controller (e.g., of a microcontroller, microprocessor, DSP, or other processor, without limitation) that issues read write commands configured to instruct drivers of BL, WL and WLB in accordance with some or a totality of operations of process 600. Additionally or alternatively, multiple logic circuits may be integrated with respective drivers of BL, WL and WLB to cause the drivers to operate in accordance with some or a totality of operations of process 600.

According to one or more examples, process 600 may include setting BitLine BL to VDD (logic ‘1’) at operation 602. In the case of a write 0, the memory cell is preconditioned to a state that corresponds to a logic ‘1’.

According to one or more examples, process 600 may include setting the WriteLine WL to VDD to enable the first access transistor at operation 604. The storage node S2, which is coupled to the output of the memory cell, is more directly influenceable via the first access transistor than via the complementary access transistor.

According to one or more examples, process 600 may include setting the complementary WriteLine WLB to 0V to disable the complementary access transistor at operation 606. With the first access transistor enabled and the complementary access transistor disabled, the BL influences the state at storage node S2, as discussed herein.

According to one or more examples, process 600 may include waiting for the storage nodes to stabilize at values the correspond to a logic ‘1’ at the memory cell at operation 608.

According to one or more examples, process 600 may include setting BL to 0V (logic ‘0’) at operation 610.

According to one or more examples, process 600 may include setting the WriteLine WL to 0V to disable the first access transistor at operation 612.

According to one or more examples, process 600 may include setting the complementary WriteLine WLB to VDD to enable the complementary access transistor at operation 614. The storage node S1, which is not coupled to the output of the memory cell, is more directly influenceable via the commentary access transistor than via the first access transistor. With the first access transistor disabled and the complementary access transistor enabled, the BL influences the state at storage node S1 as discussed herein.

According to one or more examples, process 600 may include waiting for the storage nodes to stabilize at values the correspond to a logic ‘0’ at the memory cell at operation 616.

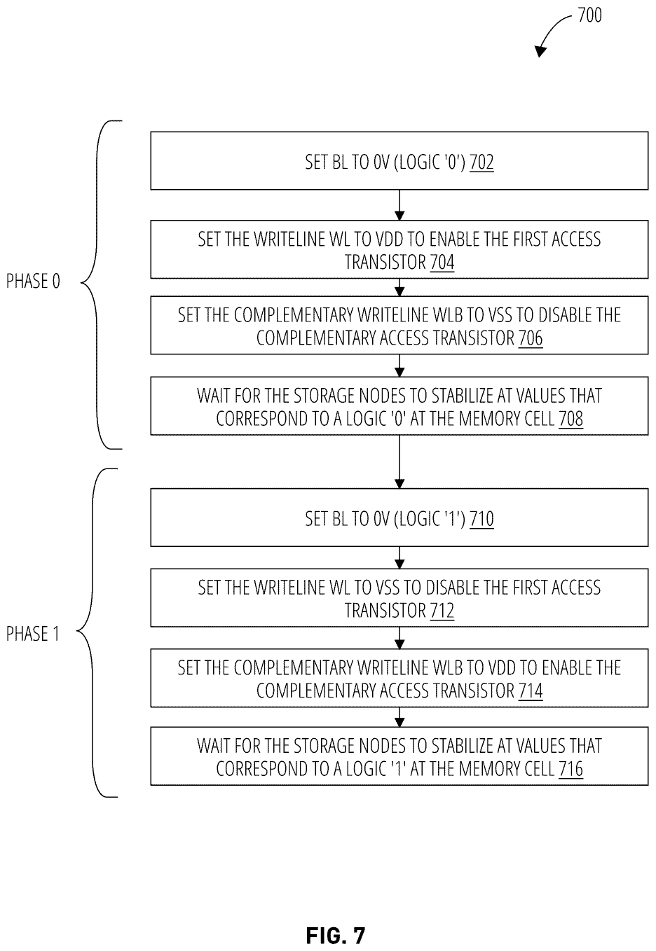

FIG. 7 illustrates an example process 700 for a two-phase wrote 1 operation to an example memory cell discussed herein (e.g., memory cell 100, memory cell 200, memory cell 300, memory cell 402), in accordance with one or more examples.

Although the example process 700 depicts a particular sequence of operations, the sequence may be altered without departing from the scope of the present disclosure. For example, some of the operations depicted may be performed in parallel or in a different sequence that does not materially affect the function of the process 700. In other examples, different components of an example device or system that implements the process 700 may perform functions at substantially the same time or in a specific sequence.

In one or more examples, some or a totality of operations of process 700 may be performed by a memory system 400.

In one or more examples, some or a totality of operations of process 700 may be performed by a logic circuit cooperatively with one or more drivers of BL, WL and WLB, discussed herein. As non-limiting examples, such as logic circuit may be integrated with a controller (e.g., of a microcontroller, microprocessor, DSP, or other processor, without limitation) that issues read write commands configured to instruct drivers of BL, WL and WLB in accordance with some or a totality of operations of process 700. Additionally or alternatively, multiple logic circuits may be integrated with respective drivers of BL, WL and WLB to cause the drivers to operate in accordance with some or a totality of operations of process 700.

According to one or more examples, process 700 may include setting BL to 0V (logic ‘0’) at process 702. Set BL to VDD (logic ‘1’).

According to one or more examples, process 700 may include setting the WriteLine WL to VDD to enable the first access transistor at operation 704.

According to one or more examples, process 600 may include setting the complementary WriteLine WLB to 0V to disable the complementary access transistor at operation 706.

According to one or more examples, process 700 may include waiting for the storage nodes to stabilize at values the correspond to a logic ‘0’ at the memory cell at operation 708.

According to one or more examples, process 700 may include setting BitLine BL to 0V (logic ‘1’) at operation 710.

According to one or more examples, process 700 may include setting the WriteLine WL to 0V to disable the first access transistor at operation 712.

According to one or more examples, process 700 may include setting the complementary WriteLine WLB to VDD to enable the complementary access transistor at operation 714.

According to one or more examples, process 700 may include waiting for the storage nodes to stabilize at values the correspond to a logic ‘1’ at the memory cell at operation 716.

Timing considerations of setting BL, WL and WLB in process 600 and process 700 depend on specific operation conditions and discussion thereof are omitted solely to economize the description.

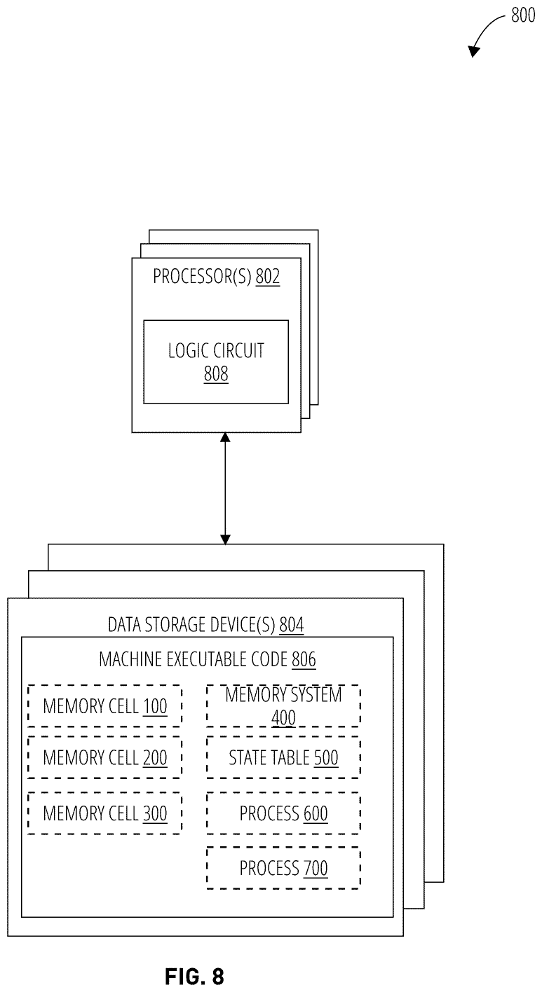

It will be appreciated by those of ordinary skill in the art that functional elements of examples disclosed herein (e.g., functions, operations, acts, processes, or methods) may be implemented in any suitable hardware, software, firmware, or combinations thereof. FIG. 8 illustrates non-limiting examples of implementations of functional elements disclosed herein. In some examples, some or all portions of the functional elements disclosed herein may be performed by hardware capable of carrying out the functional elements.

FIG. 8 is a block diagram of a circuitry 800 that, in some examples, may be used to implement various functions, operations, acts, processes, or methods disclosed herein. The circuitry 800 includes one or more processors 802 (sometimes referred to herein as “processors 802”) operably coupled to one or more data storage devices 804 (sometimes referred to herein as “storage 804”). The storage 804 includes machine-executable code 806 stored thereon and the processors 802 include logic circuit 808. The machine-executable code 806 information describing functional elements that may be implemented by (e.g., performed by) the logic circuit 808. The logic circuit 808 is adapted to implement (e.g., perform) the functional elements described by the machine-executable code 806. The circuitry 800, when executing the functional elements described by the machine-executable code 806, should be considered as special purpose hardware for carrying out functional elements disclosed herein. In some examples the processors 802 may perform the functional elements described by the machine-executable code 806 sequentially, concurrently (e.g., on one or more different hardware platforms), or in one or more parallel process streams.

When implemented by logic circuit 808 of the processors 802, the machine-executable code 806 adapts the processors 802 to perform operations of examples disclosed herein. By way of non-limiting example, the machine-executable code 806 may adapt the processors 802 to perform some or a totality of operations to store, write and read from a memory cell discussed herein, including two-phase memory reads and writes. By way of non-limiting example, the machine-executable code 806 may adapt the processors 802 to perform some or a totality of operations of process 600 or process 700, or discussed with respect to state table 500.

Also by way of non-limiting example, the machine-executable code 806 may adapt the processors 802 to perform some or a totality of features, functions, or operations disclosed herein for one or more of: memory cell 100, memory cell 200, memory cell 300, memory system 400, or state table 500.

The processors 802 may include a general purpose processor, a special purpose processor, a central processing unit (CPU), a microcontroller, a programmable logic controller (PLC), a digital signal processor (DSP), an application specific integrated circuit (ASIC), a field-programmable gate array (FPGA) or other programmable logic device, discrete gate or transistor logic, discrete hardware components, other programmable device, or any combination thereof designed to perform the functions disclosed herein. A general-purpose computer including a processor is considered a special-purpose computer while the general-purpose computer executes functional elements corresponding to the machine-executable code 806 (e.g., software code, firmware code, hardware descriptions) related to examples of the present disclosure. It is noted that a general-purpose processor (may also be referred to herein as a host processor or simply a host) may be a microprocessor, but in the alternative, the processors 802 may include any conventional processor, controller, microcontroller, or state machine. The processors 802 may also be implemented as a combination of computing devices, such as a combination of a DSP and a microprocessor, a plurality of microprocessors, one or more microprocessors in conjunction with a DSP core, or any other such configuration.

In some examples the storage 804 includes volatile data storage (e.g., random-access memory (RAM)), non-volatile data storage (e.g., Flash memory, a hard disc drive, a solid state drive, erasable programmable read-only memory (EPROM), without limitation). In some examples the processors 802 and the storage 804 may be implemented into a single device (e.g., a semiconductor device product, a system on chip (SOC), without limitation). In some examples the processors 802 and the storage 804 may be implemented into separate devices.

In some examples the machine-executable code 806 may include computer-readable instructions (e.g., software code, firmware code). By way of non-limiting example, the computer-readable instructions may be stored by the storage 804, accessed directly by the processors 802, and executed by the processors 802 using at least the logic circuit 808. Also by way of non-limiting example, the computer-readable instructions may be stored on the storage 804, transferred to a memory device (not shown) for execution, and executed by the processors 802 using at least the logic circuit 808. Accordingly, in some examples, the logic circuit 808 includes electrically configurable logic circuit 808.

In some examples the machine-executable code 806 may describe hardware (e.g., circuitry) to be implemented in the logic circuit 808 to perform the functional elements. This hardware may be described at any of a variety of levels of abstraction, from low-level transistor layouts to high-level description languages. At a high-level of abstraction, a hardware description language (HDL) such as an IEEE Standard hardware description language (HDL) may be used. By way of non-limiting examples, VERILOG®, SYSTEMVERILOG™ or very large scale integration (VLSI) hardware description language (VHDL) may be used.

HDL descriptions may be converted into descriptions at any of numerous other levels of abstraction as desired. As a non-limiting example, a high-level description can be converted to a logic-level description such as a register-transfer language (RTL), a gate-level (GL) description, a layout-level description, or a mask-level description. As a non-limiting example, micro-operations to be performed by hardware logic circuits (e.g., gates, flip-flops, registers, without limitation) of the logic circuit 808 may be described in a RTL and then converted by a synthesis tool into a GL description, and the GL description may be converted by a placement and routing tool into a layout-level description that corresponds to a physical layout of an integrated circuit of a programmable logic device, discrete gate or transistor logic, discrete hardware components, or combinations thereof. Accordingly, in some examples the machine-executable code 806 may include an HDL, an RTL, a GL description, a mask level description, other hardware description, or any combination thereof.

In examples where the machine-executable code 806 includes a hardware description (at any level of abstraction), a system (not shown, but including the storage 804) implements the hardware description described by the machine-executable code 806. By way of non-limiting example, the processors 802 may include a programmable logic device (e.g., an FPGA or a PLC) and the logic circuit 808 may be electrically controlled to implement circuitry corresponding to the hardware description into the logic circuit 808. Also by way of non-limiting example, the logic circuit 808 may include hard-wired logic manufactured by a manufacturing system (not shown, but including the storage 804) according to the hardware description of the machine-executable code 806.

Regardless of whether the machine-executable code 806 includes computer-readable instructions or a hardware description, the logic circuit 808 is adapted to perform the functional elements described by the machine-executable code 806 when implementing the functional elements of the machine-executable code 806. It is noted that although a hardware description may not directly describe functional elements, a hardware description indirectly describes functional elements that the hardware elements described by the hardware description are capable of performing.

As used in the present disclosure, the terms “module” or “component” may refer to specific hardware implementations to perform the actions of the module or component and/or software objects or software routines that may be stored on and/or executed by general purpose hardware (e.g., computer-readable media, processing devices, without limitation) of the computing system. In some examples, the different components, modules, engines, and services described in the present disclosure may be implemented as objects or processes that execute on the computing system (e.g., as separate threads). While some of the system and methods described in the present disclosure are generally described as being implemented in software (stored on and/or executed by general purpose hardware), specific hardware implementations or a combination of software and specific hardware implementations are also possible and contemplated.

As used in the present disclosure, the term “combination” with reference to a plurality of elements may include a combination of all the elements or any of various different subcombinations of some of the elements. For example, the phrase “A, B, C, D, or combinations thereof” may refer to any one of A, B, C, or D; the combination of each of A, B, C, and D; and any subcombination of A, B, C, or D such as A, B, and C; A, B, and D; A, C, and D; B, C, and D; A and B; A and C; A and D; B and C; B and D; or C and D.

Terms used in the present disclosure and especially in the appended claims (e.g., bodies of the appended claims, without limitation) are generally intended as “open” terms (e.g., the term “including” should be interpreted as “including, but not limited to,” the term “having” should be interpreted as “having at least,” the term “includes” should be interpreted as “includes, but is not limited to,” without limitation). As used herein, the term “each” means “some or a totality.” As used herein, the term “each and every” means a “totality.”

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to examples containing only one such recitation, even when the same claim includes the introductory phrases “one or more” or “at least one” and indefinite articles such as “a” or “an” (e.g., “a” and/or “an” should be interpreted to mean “at least one” or “one or more,” without limitation); the same holds true for the use of definite articles used to introduce claim recitations.

In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations, without limitation). Furthermore, in those instances where a convention analogous to “at least one of A, B, and C, without limitation” or “one or more of A, B, and C, without limitation” is used, in general such a construction is intended to include A alone, B alone, C alone, A and B together, A and C together, B and C together, or A, B, and C together, without limitation.

Further, any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.”

Additional non-limiting examples include:

Example 1: An apparatus comprising: a first inverter and a second inverter cross-coupled between a first node and a second node to store a signal state represented by voltage values at the first node and the second node, wherein the first and second inverters are configured to operate reliably under voltage conditions higher than a positive supply voltage of the apparatus; a first access transistor to selectively couple the first node to a bit line and allow direct control of the first node during access operations; and a second access transistor to selectively couple the second node to the bit line and allow direct control of the second node during access operations, wherein respective positive supply inputs of the first inverter and the second inverter to couple to a voltage supply associated with a higher voltage level than the positive supply voltage of the apparatus.

Example 2: The apparatus according to Example 1, wherein one or both of the first inverter or the second inverter includes stacked transistors to divide voltage across respective ones of the stacked transistors.

Example 3: The apparatus according to any of Examples 1 and 2, wherein a number of transistors of the stacked transistors is chosen at least partially to maintain voltage stress on a respective transistor of the stacked transistors within its respective tolerances.

Example 4: The apparatus according to any of Examples 1 through 3, comprising: at least one input to receive a bias voltage to bias gates of one or more transistors of one or both of the first inverter or the second inverter.

Example 5: The apparatus according to any of Examples 1 through 4, wherein a bias level of the bias voltage is set to manage a drain-source voltage of a respective transistor via control of a gate-source voltage of the respective transistors.

Example 6: The apparatus according to any of Examples 1 through 5, wherein a totality of transistors of the first inverter and second inverter exhibit nonuniform voltage tolerance across their respective terminal nodes.

Example 7: The apparatus according to any of Examples 1 through 6, wherein a respective transistor of one or both of the first inverter or the second inverter exhibits lower drain-source voltage tolerance than gate-drain voltage tolerance and gate-source voltage tolerance.

Example 8: The apparatus according to any of Examples 1 through 7, wherein a drain of the first access transistor is coupled to an internal node of the first inverter, and the internal node is switchably coupled to the output of the first inverter.

Example 9: The apparatus according to any of Examples 1 through 8, wherein a drain of the second access transistor is coupled to an internal node of the second inverter, and the internal node is switchably coupled to the output of the second inverter.

Example 10: The apparatus according to any of Examples 1 through 9, comprising one or more impedance elements arranged between one or more of the first node or the second node and respective outputs of the first inverter and the second inverter.

Example 11: A system, comprising: a configuration memory cell; a bit line driver coupled by a bit line to the configuration memory cell; a word line driver coupled by a word line to a gate of an access transistor of the configuration memory cell; a complementary word line driver, coupled by a commentary word line to a gate of a commentary access transistor of the configuration memory cell; and a logic circuit to control the bit line driver, word line driver, and commentary word line driver in a two-phase access operation of the configuration memory cell where the logic.

Example 12: The system according to Example 11, wherein functions of the logic circuit are respectively integrated with the bit line driver, word line driver, and commentary word line driver, and control the bit line driver, word line driver, and commentary world line driver in response to access commands.

Example 13: The system according to any of Examples 11 and 12, comprising a controller and the logic circuit is present in the controller and issues access commands to control the bit line driver, word line driver, and commentary world line driver.

Example 14: The system according to any of Examples 11 through 13, wherein the logic circuit to sequentially activate the word line and the complementary word line in access operations on the configuration memory cell in the two-phase access.

Example 15: The system according to any of Examples 11 through 14, wherein the logic circuit, in a two-phase write logic level low operation, to: set the bit line to VDD; set a write line to VDD to enable a first access transistor; set a complementary write line to VSS to disable a complementary access transistor; wait for storage node of the configuration memory cell to stabilize at values that correspond to logic high: set the bit line to VSS; set the write line to VSS to disable the first access transistor; set the complementary write line to VDD to enable the complementary access transistor; and wait for the storage nodes of the configuration memory cell to stabilize at values that correspond to a logic level low.

Example 16: The system according to any of Examples 11 through 15, wherein the logic circuit, in a two-phase write logic level low operation, to: set the bit line to VSS; set a write line to VDD to enable a first access transistor; set a complementary write line to VSS to disable a complementary access transistor; wait for storage node of the configuration memory cell to stabilize at values that correspond to logic high: set the bit line to VDD; set the write line to VSS to disable the first access transistor; set the complementary write line to VDD to enable the complementary access transistor; and wait for the storage nodes of the configuration memory cell to stabilize at values that correspond to a logic level low.

While the present disclosure has been described herein with respect to certain illustrated examples, those of ordinary skill in the art will recognize and appreciate that the present invention is not so limited. Rather, many additions, deletions, and modifications to the illustrated and described examples may be made without departing from the scope of the invention as hereinafter claimed along with their legal equivalents. In addition, features from one example may be combined with features of another example while still being encompassed within the scope of the invention as contemplated by the inventor.

What is claimed is:

1. An apparatus comprising:
a first inverter and a second inverter cross-coupled between a first node and a second node to store a signal state represented by voltage values at the first node and the second node, wherein the first and second inverters are configured to operate reliably under voltage conditions higher than a positive supply voltage of the apparatus;
a first access transistor to selectively couple the first node to a bit line and allow direct control of the first node during access operations; and
a second access transistor to selectively couple the second node to the bit line and allow direct control of the second node during access operations,
wherein respective positive supply inputs of the first inverter and the second inverter to couple to a voltage supply associated with a higher voltage level than the positive supply voltage of the apparatus.

2. The apparatus of claim 1, wherein one or both of the first inverter or the second inverter includes stacked transistors to divide voltage across respective ones of the stacked transistors.

3. The apparatus of claim 2, wherein a number of transistors of the stacked transistors is chosen at least partially to maintain voltage stress on a respective transistor of the stacked transistors within its respective tolerances.

4. The apparatus of claim 1, comprising:
at least one input to receive a bias voltage to bias gates of one or more transistors of one or both of the first inverter or the second inverter.

5. The apparatus of claim 4, wherein a bias level of the bias voltage is set to manage a drain-source voltage of a respective transistor via control of a gate-source voltage of the respective transistors.

6. The apparatus of claim 1, wherein a totality of transistors of the first inverter and second inverter exhibit nonuniform voltage tolerance across their respective terminal nodes.

7. The apparatus of claim 1, wherein a respective transistor of one or both of the first inverter or the second inverter exhibits lower drain-source voltage tolerance than gate-drain voltage tolerance and gate-source voltage tolerance.

8. The apparatus of claim 1, wherein a drain of the first access transistor is coupled to an internal node of the first inverter, and the internal node is switchably coupled to the output of the first inverter.

9. The apparatus of claim 1, wherein a drain of the second access transistor is coupled to an internal node of the second inverter, and the internal node is switchably coupled to the output of the second inverter.

10. The apparatus of claim 1, comprising one or more impedance elements arranged between one or more of the first node or the second node and respective outputs of the first inverter and the second inverter.

11. A system, comprising:
a configuration memory cell;
a bit line driver coupled by a bit line to the configuration memory cell;
a word line driver coupled by a word line to a gate of an access transistor of the configuration memory cell;
a complementary word line driver, coupled by a commentary word line to a gate of a commentary access transistor of the configuration memory cell; and
a logic circuit to control the bit line driver, word line driver, and commentary word line driver in a two-phase access operation of the configuration memory cell where the logic.

12. The system of claim 11, wherein functions of the logic circuit are respectively integrated with the bit line driver, word line driver, and commentary word line driver, and control the bit line driver, word line driver, and commentary world line driver in response to access commands.

13. The system of claim 11, comprising a controller and the logic circuit is present in the controller and issues access commands to control the bit line driver, word line driver, and commentary world line driver.

14. The system of claim 11, wherein the logic circuit to sequentially activate the word line and the complementary word line in access operations on the configuration memory cell in the two-phase access.

15. The system of claim 14, wherein the logic circuit, in a two-phase write logic level low operation, to:
set the bit line to VDD;
set a write line to VDD to enable a first access transistor;
set a complementary write line to VSS to disable a complementary access transistor;
wait for storage node of the configuration memory cell to stabilize at values that correspond to logic high:
set the bit line to VSS;
set the write line to VSS to disable the first access transistor;
set the complementary write line to VDD to enable the complementary access transistor; and
wait for the storage nodes of the configuration memory cell to stabilize at values that correspond to a logic level low.

16. The system of claim 14, wherein the logic circuit, in a two-phase write logic level low operation, to:
set the bit line to VSS;
set a write line to VDD to enable a first access transistor;
set a complementary write line to VSS to disable a complementary access transistor;
wait for storage node of the configuration memory cell to stabilize at values that correspond to logic high:
set the bit line to VDD;
set the write line to VSS to disable the first access transistor;
set the complementary write line to VDD to enable the complementary access transistor; and
wait for the storage nodes of the configuration memory cell to stabilize at values that correspond to a logic level low.
